(19) United States
(12) Patent Application Publication
(10) Pub. No.: US 2017/0077129 A1
(43) Pub. Date: Mar. 16, 2017

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventor: Masako KINOSHITA, Yokkaichi (JP)

(73) Assignee: Kabushiki Kaisha Toshiba, Minato-ku (JP)

(21) Appl. No.: 15/050,788

(22) Filed: Feb. 23, 2016

Related U.S. Application Data
(60) Provisional application No. 62/217,429, filed on Sep. 11, 2015.

(51) Int. Cl. H01L 27/115

(52) U.S. Cl. CPC H01L 27/11582; H01L 27/11556

(57) ABSTRACT

According to one embodiment, a semiconductor memory device includes a stacked body, a semiconductor pillar, a memory film and a first contact portion. The stacked body includes a first electrode film, a second electrode film and an inter-electrode insulating film. The second electrode film is arranged with the first electrode film in a first direction. The inter-electrode insulating film is provided between the first electrode film and the second electrode film. The first electrode film includes a first edge portion. The first edge portion does not overlap the second electrode film in the first direction. The semiconductor pillar is provided in the stacked body. The semiconductor pillar extends in the first direction. The memory film is provided between the semiconductor pillar and the first electrode film. The first contact portion extending in the first direction and overlaps the first edge portion in the first direction.

### CROSS-REFERENCE TO RELATED APPLICATIONS

This application is based upon and claims the benefit of priority from U.S. provisional patent application 62/217,429, filed on Sep. 11, 2015; the entire contents of which are incorporated herein by reference.

### FIELD

Embodiments described herein relate generally to a semiconductor device and a method for manufacturing the same. The semiconductor includes a contact portion. The contact portion includes a portion of a reverse-tapered shape.

### BACKGROUND

A stacked type semiconductor memory device including a semiconductor pillar extending in a first direction, a stacked body provided around the semiconductor pillar with the semiconductor pillar as an axis and including electrode films and insulating films, and contacts disposed at a stepped pattern portion of the stacked body has been proposed. In the stacked type semiconductor memory device, it is desired that the radius of a circumscribed circle in a cross-section of the contact crossing the first direction be small.

### BRIEF DESCRIPTION OF THE DRAWINGS

FIG. 1 is a schematic perspective view illustrating a semiconductor memory device according to a first embodiment;

FIG. 2A is a schematic sectional view illustrating a portion of the semiconductor memory device according to the first embodiment;

FIG. 2B is a schematic sectional view taken along the line C1-C2 shown in FIG. 1;

FIGS. 3A, 3B and 3C are an enlarged view of a portion PD of FIG. 2B;

FIG. 4A to FIG. 7 are schematic sectional views illustrating the method for manufacturing the semiconductor memory device according to the first embodiment;

FIG. 4A, FIG. 4B, and FIG. 7 are schematic sectional views taken along the line D1-D2 shown in FIG. 1;

FIG. 5A to FIG. 6D are schematic sectional views taken along the line C1-C2 shown in FIG. 1;

FIG. 8A is a schematic perspective view of a memory device according to a second embodiment; and

FIG. 8B is a schematic sectional view taken along the line F1-F2 shown in FIG. 8A.

### DETAILED DESCRIPTION

According to one embodiment, a semiconductor memory device includes a stacked body, a semiconductor pillar, a memory film and a first contact portion. The stacked body includes a first electrode film, a second electrode film and an inter-electrode insulating film. The second electrode film is arranged with the first electrode film in a first direction. The inter-electrode insulating film is provided between the first electrode film and the second electrode film. The first electrode film includes a first edge portion. The first edge portion does not overlap the second electrode film in the first direction. The semiconductor pillar is provided in the stacked body. The semiconductor pillar extends in the first direction. The memory film is provided between the semiconductor pillar and the first electrode film and provided between the semiconductor pillar and the second electrode film. The first contact portion extends in the first direction. The first contact portion overlaps the first edge portion in the first direction and electrically connected to the first edge portion. The first contact portion includes a first core material portion, a first conductive film and a second conductive film. The first core material portion extends in the first direction. The first conductive film is provided around the first core material portion. The first conductive film includes a first portion and a second portion. The second portion is disposed between the first portion and the first edge portion. The second conductive film is provided around the first portion. A first length of the first conductive film along the first direction is longer than a second length of the second conductive film along the first direction.

Hereinafter, some embodiments of the invention will be explained with reference to the accompanying drawings.

### First Embodiment

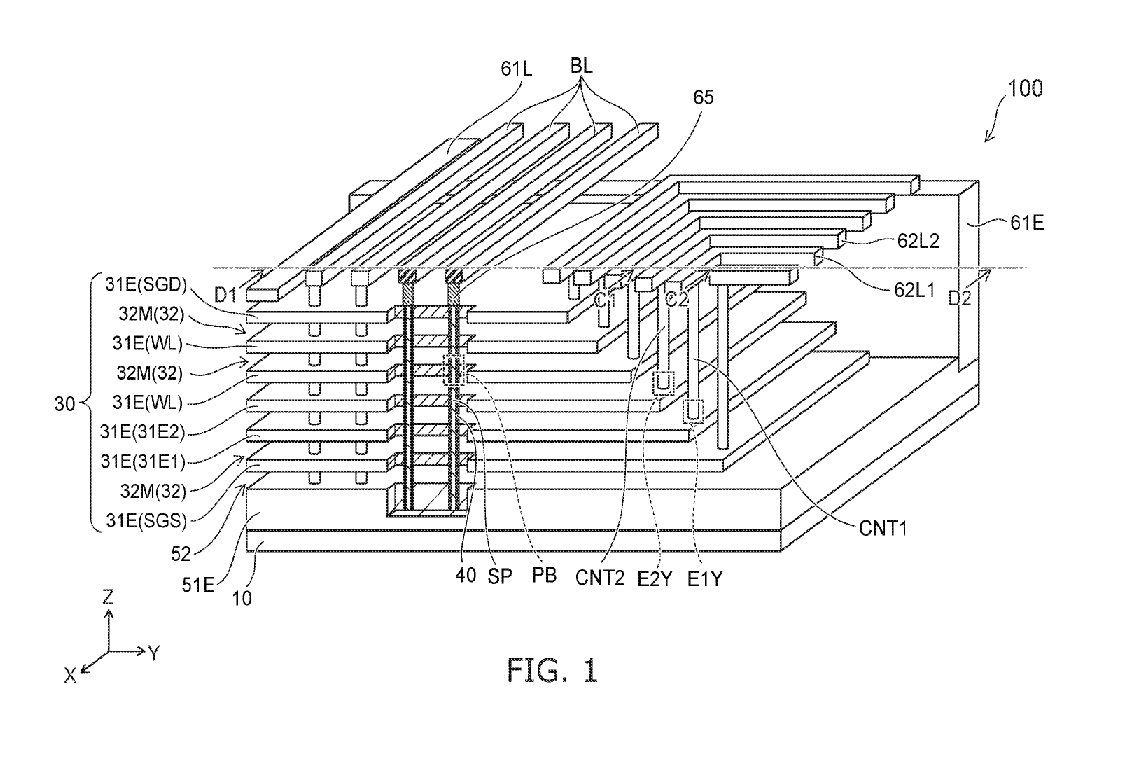

FIG. 1 is a schematic perspective view illustrating a semiconductor memory device according to a first embodiment.

As shown in FIG. 1, in the semiconductor memory device 100 according to the first embodiment, a substrate 10 is provided. In this example, a conductive layer 51E is provided on the substrate 10. The conductive layer 51E includes, for example, interconnects.

A first contact portion CNT1 and semiconductor pillars SP are provided on the substrate 10 (on the conductive layer 51E in this example).

An extending direction of the first contact portion CNT1 is defined as a “first direction”. A direction crossing the first direction is defined as a “second direction”. A direction crossing the first direction and the second direction is defined as a “third direction”. The “first direction” is defined as, for example, a “Z-direction”. A direction perpendicular to the Z-direction is defined as an “X-direction”. A direction perpendicular to the Z-direction and the X-direction is defined as a “Y-direction”.

In the specification of the application, a state where a second element is provided on a first element includes a state where the second element is in physical contact with the first element and a state where a third element is provided between the second element and the first element.

Also the semiconductor pillar SP extends in the Z-direction. At least a portion of the semiconductor pillar SP is arranged with at least a portion of the first contact portion CNT1 in a direction crossing the Z-direction.

A stacked body 30 is provided around the semiconductor pillar SP with the semiconductor pillar SP as an axis. The stacked body 30 includes a plurality of electrode films 31E and a plurality of inter-electrode insulating films 32M alternately arranged in the Z-direction. One of the plurality of electrode films 31E is defined as a first electrode film 31E1. One of the plurality of electrode films 31E is defined as a second electrode film 31E2. The second electrode film 31E2 is located higher than the first electrode film 31E1 in the Z-direction. An inter-electrode insulating film 32 as one of the plurality of inter-electrode insulating films 32M is provided between the first electrode film 31E1 and the second electrode film 31E2. In the embodiment, another electrode film 31E may be provided between the first electrode film 31E1 and the second electrode film 31E2. In the following, as shown in FIG. 1, an example of the case where another electrode film 31E is not provided between the first electrode film 31E1 and the second electrode film 31E2 will be described.

The positions (positions in the Y-direction) of edge portions of the plurality of electrode films 31E are different from one another. The edge portions of the plurality of electrode films 31E have a stepped pattern.

For example, the first electrode film 31E1 includes a first edge portion E1Y in the Y-direction. The first edge portion E1Y does not overlap the second electrode film 31E2 in the Z-direction. The second electrode film 31E2 is provided on the first electrode film 31E1 except at the first edge portion E1Y. The second electrode film 31E2 is not provided on the first edge portion E1Y.

As described above, on the edge portion (edge portion in the Y-direction) of “one electrode film 31E” of the plurality of electrode films 31E, another electrode film 31E located on the “one electrode film 31E1” is not provided.

A memory film 40 is provided between the semiconductor pillar SP and the stacked body 30. The semiconductor pillar SP pierces the stacked body 30 along the Z-direction.

A memory cell MC is formed at a crossing portion between one of the plurality of electrode films 31E and the semiconductor pillar SP. By changing a voltage applied to the electrode film 31E, electrical charges are stored in the memory film 40, or electrical charges are discharged from the memory film 40. The electrode film 31E functions as a word line WL of the memory cell MC.

As described above, at least a portion of the plurality of electrode films 31E serves as the word line WL. In this example, a drain-side select gate electrode SGD is provided on a plurality of the word lines WL. Further, a source-side select gate electrode SGS is provided below the word lines WL. For example, at least any of the drain-side select gate electrode SGD and the source-side select gate electrode SGS may be included in one of the plurality of electrode films 31E. Arrangements such as the arrangement of the drain-side select gate electrode SGD and the source-side select gate electrode SGS may be different from the arrangements shown in FIG. 1 depending on the configuration of a memory portion. Bit lines BL are provided on the semiconductor pillars SP.

The bit line BL extends in the X-direction. Contact portions 65 extending in the Z-direction are provided between the semiconductor pillars SP and the bit lines BL. The semiconductor pillar SP and the bit line BL are electrically connected through the contact portion 65.

In this example, a conductive layer 61E is provided on the substrate 10. The conductive layer 61E is provided to be along an YZ plane. The conductive layer 61E is electrically connected to the conductive layer 51E. An interconnect 61L is provided on the conductive layer 61E. The interconnect 61L extends in the X-direction. A contact portion (not shown) extending in the Z-direction is provided between the conductive layer 61E and the interconnect 61L.

The first contact portion CNT1 is provided on the first edge portion E1Y of the first electrode film 31E1. The first contact portion CNT1 extends in the Z-direction. The first electrode film 31E1 and the first contact portion CNT1 are electrically connected to each other. An interconnect 62L1 is provided on the first contact portion CNT1. The interconnect 62L1 extends in the Y-direction. The first contact portion CNT1 and the interconnect 62L1 are electrically connected to each other.

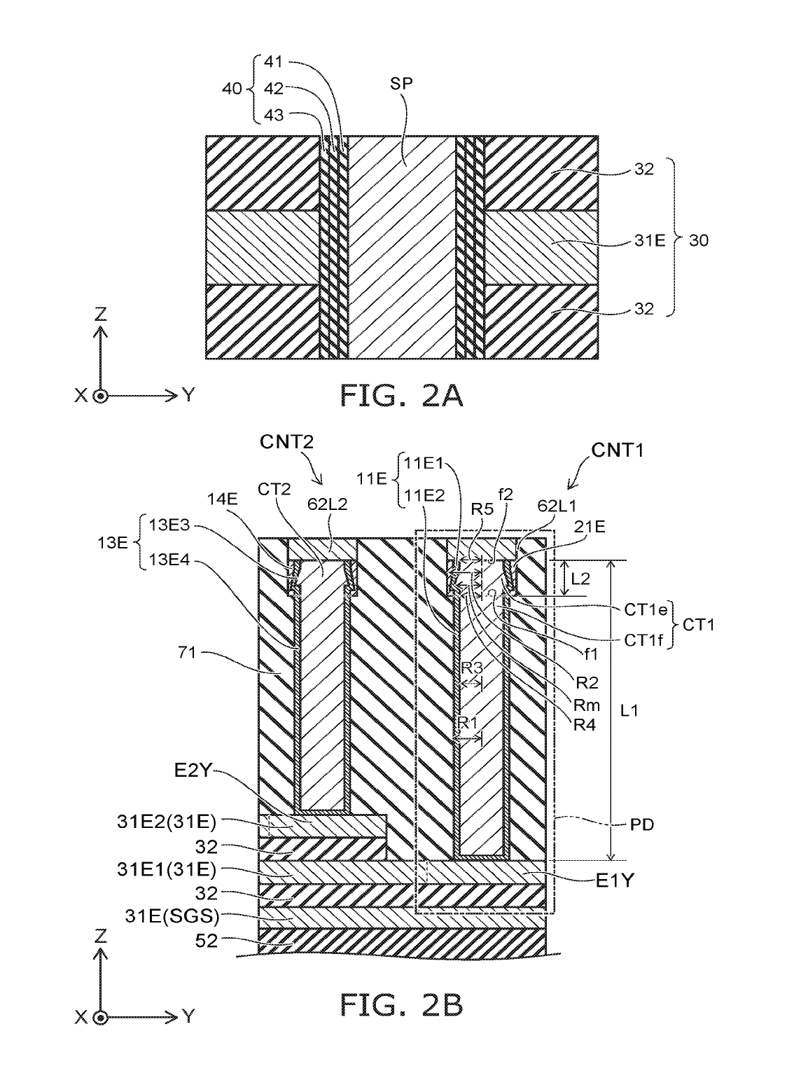

FIG. 2A is a schematic sectional view illustrating a portion of the semiconductor memory device according to the first embodiment.

FIG. 2A is an enlarged view of a portion PB of FIG. 1.

As shown in FIG. 2A, in the portion PB of FIG. 1, an outer insulating film 43 is provided between the semiconductor pillar SP and the stacked body 30. The outer insulating film 43 is, for example, a block insulating film. An intermediate film 42 is provided between the outer insulating film 43 and the semiconductor pillar SP. The intermediate film 42 is, for example, a charge storage film. An inner insulating film 41 is provided between the intermediate film 42 and the semiconductor pillar SP. The inner insulating film 41 is, for example, a tunnel insulating film. The inner insulating film 41, the intermediate film 42, and the outer insulating film 43 are included in the memory film 40.

FIG. 2B is a schematic sectional view taken along the line C1-C2 shown in FIG. 1.

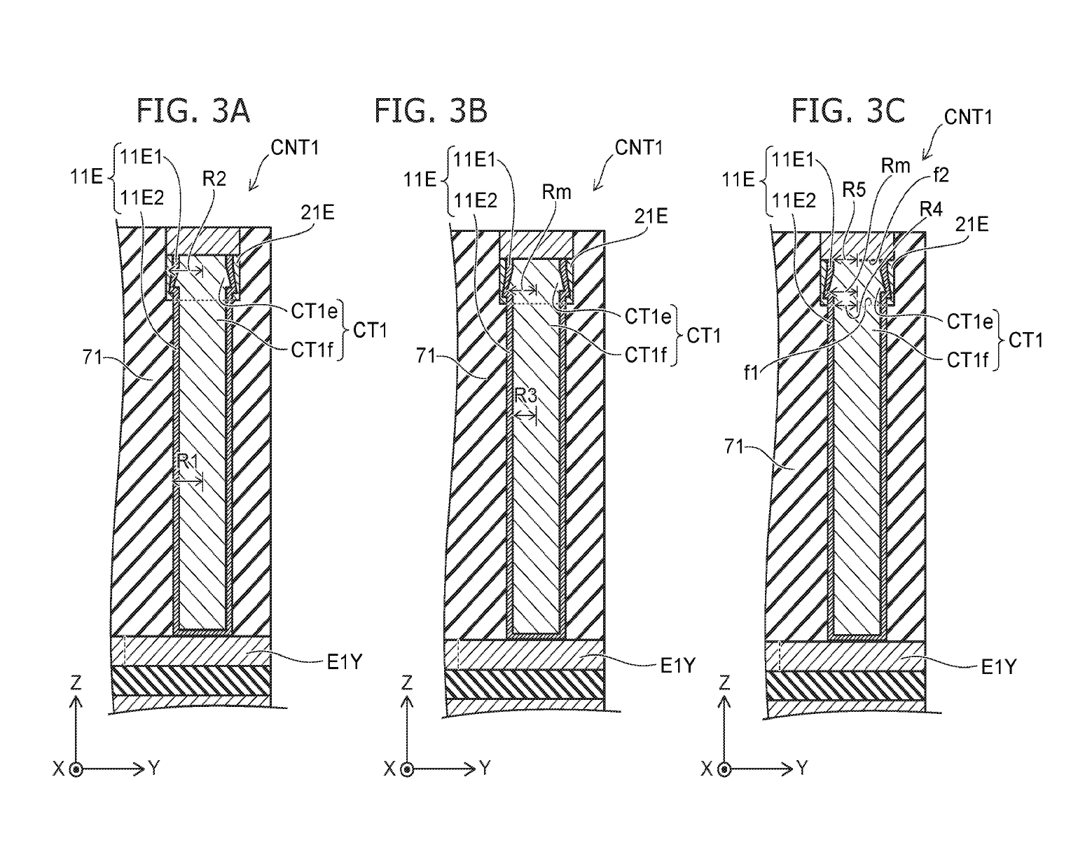

FIG. 3A is an enlarged view of a portion PD of FIG. 2B.

As shown in FIG. 2B and FIG. 3A, the first contact portion CNT1 extending in the Z-direction as described above is provided on the first edge portion E1Y of the first electrode film 31E1. The first contact portion CNT1 is electrically connected to the first edge portion E1Y. The first contact portion CNT1 is arranged with the semiconductor pillar SP in the Y-direction. The first contact portion CNT1 overlaps the first edge portion E1Y in the Z-direction. The first contact portion CNT1 is separated from the second electrode film 31E2 in the Y-direction.

A first insulating member 71 is provided around the first contact portion CNT1 with the first contact portion CNT1 as an axis. The first contact portion CNT1 pierces the first insulating member 71 along the Z-direction.

The first contact portion CNT1 includes a first core material portion CT1, a first conductive film 11E, and a second conductive film 21E. The first core material portion CT1 extends in the Z-direction. The first conductive film 11E is provided around the first core material portion CT1 with the Z-direction as an axis. The first conductive film 11E includes a first portion 11E1 and a second portion 11E2. The second portion 11E2 is disposed between the first portion 11E1 and the first edge portion E1Y. The second conductive film 21E is provided around the first portion 11E1 with the Z-direction as an axis.

The first core material portion CT1 includes a fifth portion CT1e overlapping the first portion 11E1 in a direction crossing the Z-direction, and a sixth portion CT1f overlapping the second portion 11E2 in the direction crossing the Z-direction. The sixth portion CT1f is disposed between the fifth portion CT1e and the first edge portion E1Y.

The second conductive film 21E is provided around the first portion 11E1 so as to cover the first portion 11E1. The shape of the first portion 11E1 of the first conductive film 11E is gradually narrowed from a portion close to the second portion 11E2 toward the Z-direction. The second conductive film 21E is not provided between the second portion 11E2 and the first insulating member 71. The first portion 11E1 and the second conductive film 21E overlap each other in the direction crossing the Z-direction. The second portion 11E2 and the second conductive film 21E do not overlap each other in the direction crossing the Z-direction.

A first length L1 of the first conductive film 11E in the Z-direction is longer than a second length L2 of the second conductive film 21E in the Z-direction.

A second contact portion CNT2 extending in the Z-direction is provided on a second edge portion E2Y of the second electrode film 31E2 in the Y-direction. The second contact portion CNT2 is electrically connected to the second edge portion E2Y. The second contact portion CNT2 is arranged with the semiconductor pillar SP and the first contact portion CNT1 in the Y-direction. The second contact portion CNT2 overlaps the second edge portion E2Y in the Z-direction. The first insulating member 71 is further provided around the second contact portion CNT2 with the second contact portion CNT2 as an axis. The second contact portion CNT2 pierces the first insulating member 71 along the Z-direction.

The second contact portion CNT2 has a configuration similar to that of the first contact portion CNT1. That is, the second contact portion CNT2 includes a second core material portion CT2, a third conductive film 13E, and a fourth conductive film 14E. The second core material portion CT2 extends in the Z-direction. The third conductive film 13E is provided around the second core material portion CT2 with the Z-direction as an axis. The third conductive film 13E includes a third portion 13E3 and a fourth portion 13E4. The fourth portion 13E4 is disposed between the third portion 13E3 and the second edge portion E2Y. The fourth conductive film 14E is provided around the third portion 13E3 with the Z-direction as an axis.

An interconnect 62L2 is provided on the second contact portion CNT2. The interconnect 62L2 extends in the Y-direction. The second contact portion CNT2 and the interconnect 62L2 are electrically connected.

As shown in FIG. 3A, a first radius R1 of a circumscribed circle of a cross-section of the second portion 11E2 crossing the Z-direction is, for example, smaller than a second radius R2 of a circumscribed circle of a cross-section of the second conductive film 21E crossing the Z-direction.

A radius of a circumscribed circle of a cross-section of the first portion 11E1 crossing the Z-direction is, for example, smaller than the second radius R2 of the circumscribed circle of the cross-section of the second conductive film 21E crossing the Z-direction.

FIG. 3B and FIG. 3C are enlarged views of the portion PD of FIG. 2B.

As shown in FIG. 3B, a maximum radius Rm of a circumscribed circle of a cross-section of the fifth portion CT1e of the first core material portion CT1 crossing the Z-direction is larger than a third radius R3 of a circumscribed circle of a cross-section of the sixth portion CT1f of the first core material portion CT1 crossing the Z-direction.

As shown in FIG. 3C, the fifth portion CT1e includes a first face f1 facing the sixth portion CT1f, and a second face f2 separated from the first face in the Z-direction. The maximum radius Rm of the fifth portion CT1e is, for example, larger than a fourth radius R4 of a circumscribed circle in the first face f1. The maximum radius Rm of the fifth portion CT1e is, for example, larger than a fifth radius R5 of a circumscribed circle in the second face f2. The sectional shape of the fifth portion CT1e in the YZ plane has a substantially trapezoid shape (reverse-tapered shape) with the top side shorter than the base.

Hereinafter, an example of the material of each portion will be shown.

The substrate 10 includes, for example, silicon (Si). The electrode film 31E includes, for example, tungsten (W). Any of the first conductive film 11E and the third conductive film 13E includes, for example, tungsten (W). Any of the second conductive film 21E and the fourth conductive film 14E includes, for example, titanium (Ti), titanium and titanium nitride (TiN), or titanium nitride and tungsten. The first insulating member 71 includes, for example, silicon oxide (SiO₂). The inter-electrode insulating film 32 includes, for example, silicon oxide. Any of the inner insulating film 41 and the outer insulating film 43 includes, for example, silicon oxide. The intermediate film 42 includes, for example, silicon nitride (SiN). Any of the interconnect 61L, the interconnect 62L1, and the interconnect 62L2 includes, for example, tungsten. Any of the first core material portion CT1, the second core material portion CT2, and the contact portion 65 includes, for example, tungsten. The bit line BL includes, for example, tungsten. Any of the second conductive film 21E and the fourth conductive film 14E includes, for example, an oxide containing any of titanium and aluminum (Al).

An example of a method for manufacturing the semiconductor memory device according to the embodiment will be described.

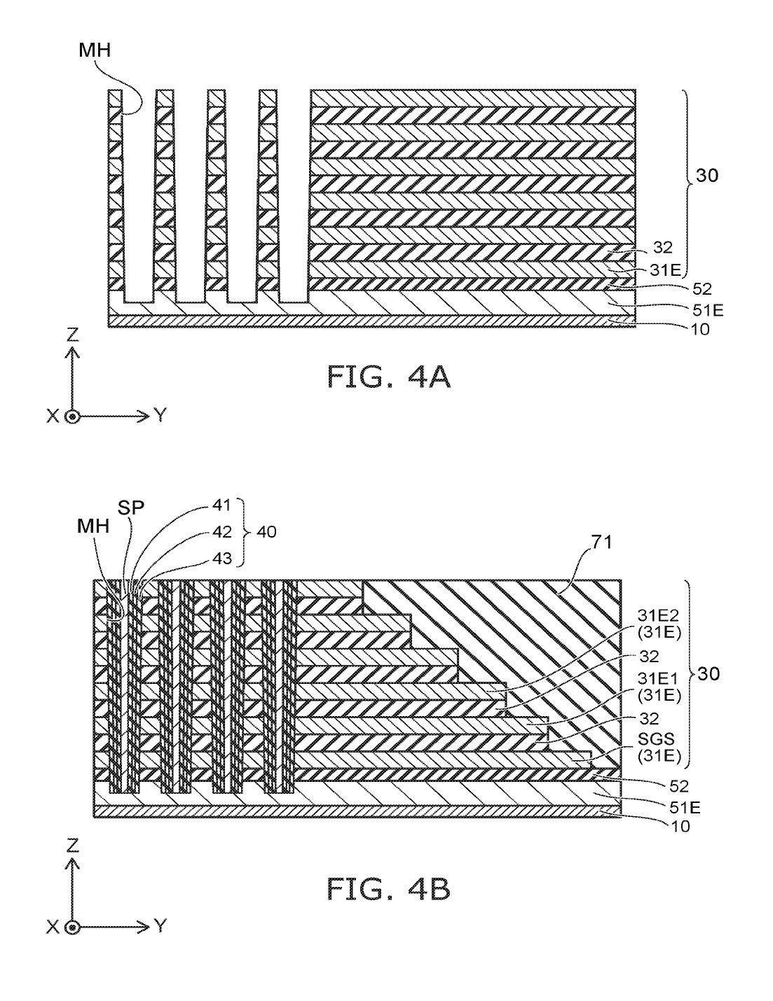

FIG. 4A to FIG. 7 are schematic sectional views illustrating the method for manufacturing the semiconductor memory device according to the first embodiment.

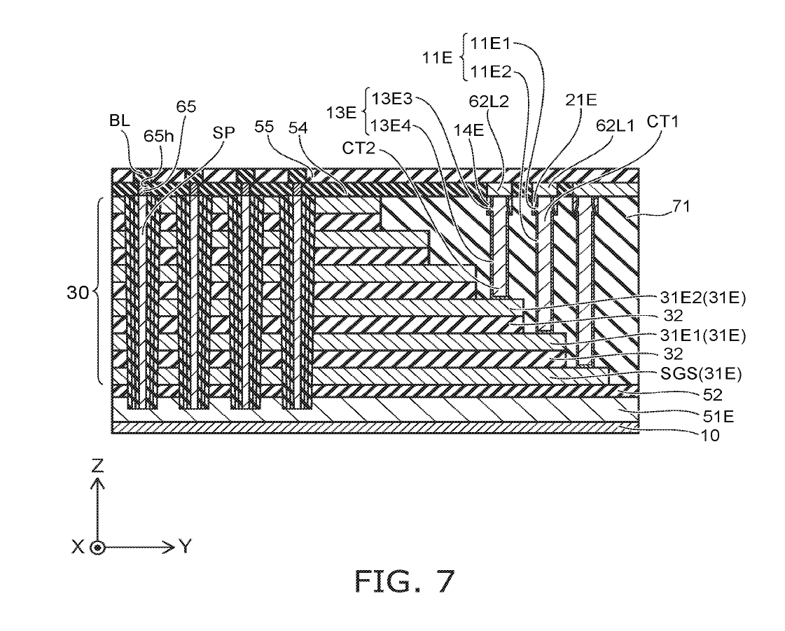

FIG. 4A, FIG. 4B, and FIG. 7 are schematic sectional views taken along the line D1-D2 shown in FIG. 1.

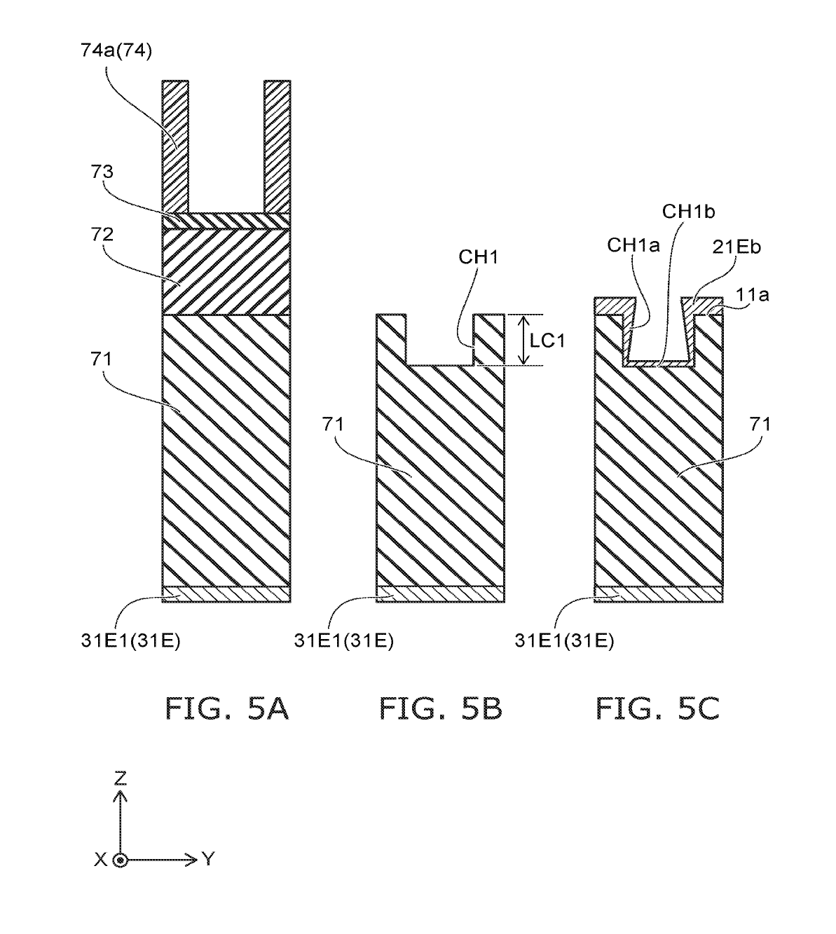

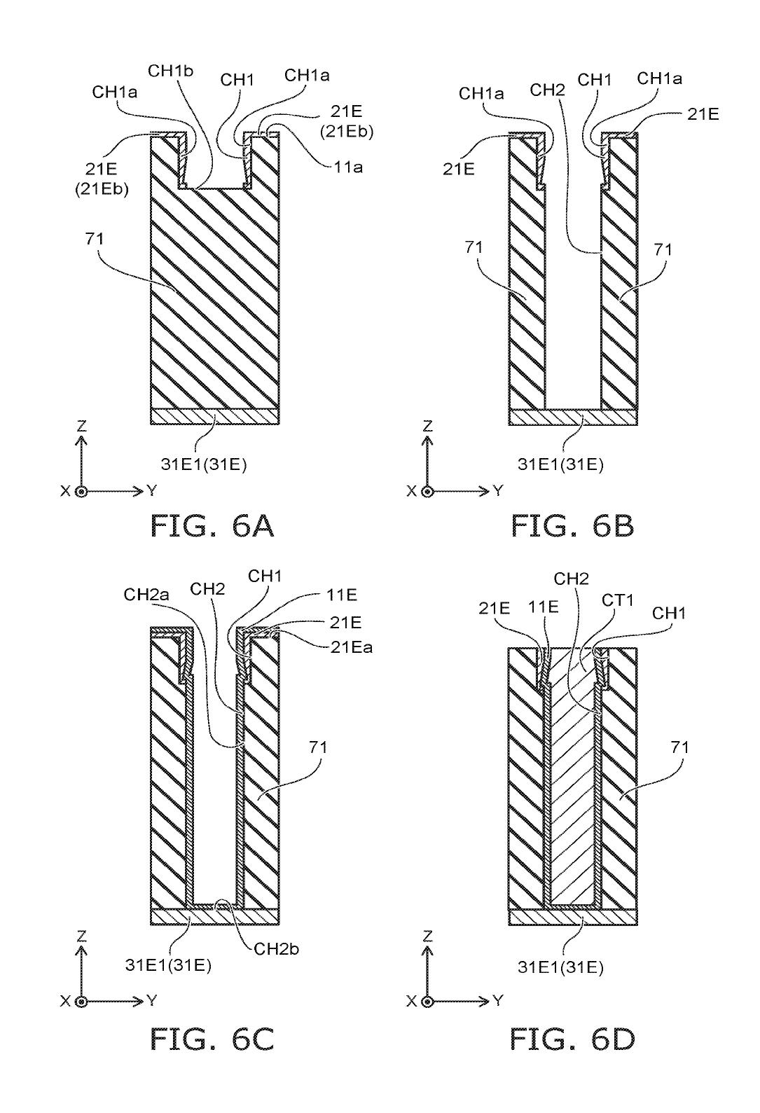

FIG. 5A to FIG. 6D are schematic sectional views taken along the line C1-C2 shown in FIG. 1.

As shown in FIG. 4A, the conductive layer 51E is formed on the substrate 10. An insulating film 52 is formed on the conductive layer 51E. The plurality of electrode films 31E and the plurality of inter-electrode insulating films 32 are stacked in the Z-direction on the insulating film 52 to form the stacked body 30. Each of the plurality of electrode films 31E includes, for example, tungsten. Each of the plurality of inter-electrode insulating films 32 includes, for example, silicon oxide.

Etching is performed on the stacked body 30. By performing the etching, memory holes MH piercing the stacked body 30 and the insulating film 52 are formed. The memory hole MH reaches the conductive layer 51E.

As shown in FIG. 4B, the outer insulating film 43 is formed on an inner face of the memory hole MH. The intermediate film 42 is formed on a surface of the outer insulating film 43. The inner insulating film 41 is formed on a surface of the intermediate film 42. The semiconductor pillar SP is formed in the memory hole MH. An edge portion of the stacked body 30 in the Y-direction is processed into a stepped pattern. A first edge portion included in one of the plurality of electrode films 31E is exposed. The first edge portion includes an edge of the stacked body 30 in the Y-direction. The one electrode film 31E including the first edge portion is referred to as the first electrode film 31E1. For example, silicon oxide is deposited on the first electrode film 31E1 and on the insulating film 52. The silicon oxide is deposited using, for example, TEOS (Tetra Ethyl Ortho Silicate: Si(OC₂H₅)₄) as a raw material by a CVD (Chemical Vapor Deposition) method. Due to this, the first insulating member 71 is formed.

As shown in FIG. 5A, a coating film 72 is formed on the first insulating member 71. An SOG (Spin On Glass) film 73 is formed on the coating film 72. A resist film 74 is formed on the SOG film 73. The resist film 74 is exposed and developed to form a resist film 74a.

As shown in FIG. 5B, for example, RIE (Reactive Ion Etching) is performed on the resist film 74a. By the RIE, a first contact hole CH1 is formed in an upper portion of the first insulating member 71. By the RIE, the coating film 72, the SOG film 73, and the resist film 74a are removed. The first contact hole CH1 does not pierce the first insulating member 71, and does not reach the first electrode film 31E1. A length LC1 of the first contact hole CH1 in the Z-direction is, for example, about 100 nm (nanometer).

As shown in FIG. 5C, for example, titanium (Ti) is deposited on a side face CH1a (face parallel to the Z-direction) of the first contact hole CH1, on a bottom face CH1b (face crossing the Z-direction) of the first contact hole CH1, and on an upper face 11a of the first insulating member 71. Due to this, a second conductive base film 21Eb is formed. Titanium is deposited by, for example, a PVD (Physical Vapor Deposition) method. In the second conductive base film 21Eb, a film thickness on the bottom face CH1b is formed thinner than a film thickness on the side face CH1a or the upper face 11a. For example, in PECVD (Plasma Enhanced CVD), a portion of the hole close to the surface (the upper face 11a) is likely to be exposed to plasma, and sufficiently supplied with gas, and therefore, the second conductive base film 21Eb is formed thick.

The second conductive base film 21Eb may be formed of, for example, titanium nitride (TiN), a stacked film of titanium and titanium nitride, or a stacked film of titanium nitride and tungsten. The second conductive base film 21Eb may be formed of, for example, an oxide containing any of titanium and aluminum.

As shown in FIG. 6A, the second conductive base film 21Eb is etch-backed (first etching). The second conductive base film 21Eb provided on the bottom face CH1b is formed thinner than the second conductive base film 21Eb provided on the side face CH1a, and thus is removed. The second conductive base film 21Eb provided on the side face CH1a is formed thicker than the second conductive base film 21Eb provided on the bottom face CH1b. For this reason, the second conductive base film 21Eb provided on the side face CH1a is not removed entirely. A portion of the second conductive base film 21Eb provided on the side face CH1a remains. Since a portion of the second conductive base film 21Eb remains, the second conductive film 21E is formed. Due to this, the second conductive film 21E can be used as an etching preventing film (mask material) in second etching performed in a later process.

As shown in FIG. 6B, for example, RIE (second etching) is performed on the entire face. At this time, the second conductive film 21E functions as an etching preventing film. As a result, a portion of the first insulating member 71 is removed in a direction from the bottom face CH1b of the first contact hole CH1 toward the first electrode film 31E1.

Due to this, a second contact hole CH2 piercing the first insulating member 71 to reach the first electrode film 31E1 is formed. The second conductive film 21E provided on the side face CH1a functions as an etching preventing film, and protects the first insulating member 71 provided on an outer circumference of the side face CH1a of the first contact hole CH1. The first insulating member 71 at a portion protected by the second conductive film 21E is hard to be removed. Hence, the second contact hole CH2 is less likely to have a bowing shape in which the width is widened on the way to a bottom face CH2b (face crossing the Z-direction).

As shown in FIG. 6C, the first conductive film 11E is formed on a side face CH2a (face parallel to the Z-direction) of the second contact hole CH2, on the bottom face CH2b (face crossing the Z-direction) of the second contact hole CH2, and on an upper face 21Ea of the second conductive film 21E. Due to this, a two-layered structure composed of the first conductive film 11E and the second conductive film 21E is formed.

As shown in FIG. 6D, the remaining space in the second contact hole CH2 is filled with a conductive material, so that the first core material portion CT1 is formed. The conductive material is, for example, tungsten. CMP (Chemical Mechanical Polishing) is performed on the first conductive film 11E, the second conductive film 21E, and the first core material portion CT1. Due to this, an upper portion of the first contact portion CNT1 including the first core material portion CT1, the first conductive film 11E, and the second conductive film 21E is planarized.

In the same manner as the formation of the second conductive film 21E, the fourth conductive film 14E is formed. In the same manner as the formation of the first conductive film 11E, the third conductive film 13E is formed. In the same manner as the formation of the first core material portion CT1, the second core material portion CT2 is formed. In this manner, the second contact portion CNT2 is formed.

As shown in FIG. 7, the interconnect 62L1 extending in the Y-direction is formed on the first contact portion CNT1. The interconnect 62L2 is formed on the second contact portion CNT2. An insulating film 54 is formed on the stacked body 30, the first insulating member 71, and the semiconductor pillars SP. Contact holes 65h piercing the insulating film 54 in the Z-direction to reach the semiconductor pillars SP are formed. The contact hole 65h is filled with, for example, tungsten to form the contact portion 65. The bit lines BL extending in the X-direction are formed on the contact portions 65. An insulating film 55 is formed between the bit lines BL.

A contact may be provided on an electrode film of the plurality of electrode films 31E other than the first electrode film 31E1 and the second electrode film 31E2.

In this manner, the semiconductor memory device 100 is formed.

In the method for manufacturing the semiconductor memory device 100 according to the embodiment, the film thickness of the second conductive base film 21Eb on the side face CH1a and the upper face 11a is formed thick, and the film thickness of the second conductive base film 21Eb on the bottom face CH1b is formed thin (see FIG. 5C). Due to this, in the first etching, the second conductive base film 21Eb remains on the side face CH1a and the upper face 11a (see FIG. 6A). In the second etching, this remaining second conductive base film 21Eb functions as an etching preventing film (mask material). As a result, the hole diameter of the formed second contact hole CH2 is not widened. That is, the second contact hole CH2 is less likely to have a bowing shape. Due to this, the radius of the circumscribed circle of the cross-section of the first contact portion CNT1 crossing the Z-direction becomes small compared with the case where the second conductive film 21E is not provided. As a result, it is possible to inhibit contact between the contact portions.

Moreover, in the semiconductor memory device 100 according to the embodiment, the shape of the contact portion is less likely to be a bowing shape, and has no wide portion. For this reason, compared with the case of having a bowing shape, a distance between the contact portion (CNT1) and another contact portion (CNT2) can be increased. As a result, the capacitance between the contact portion and another contact portion can be reduced.

### Second Embodiment

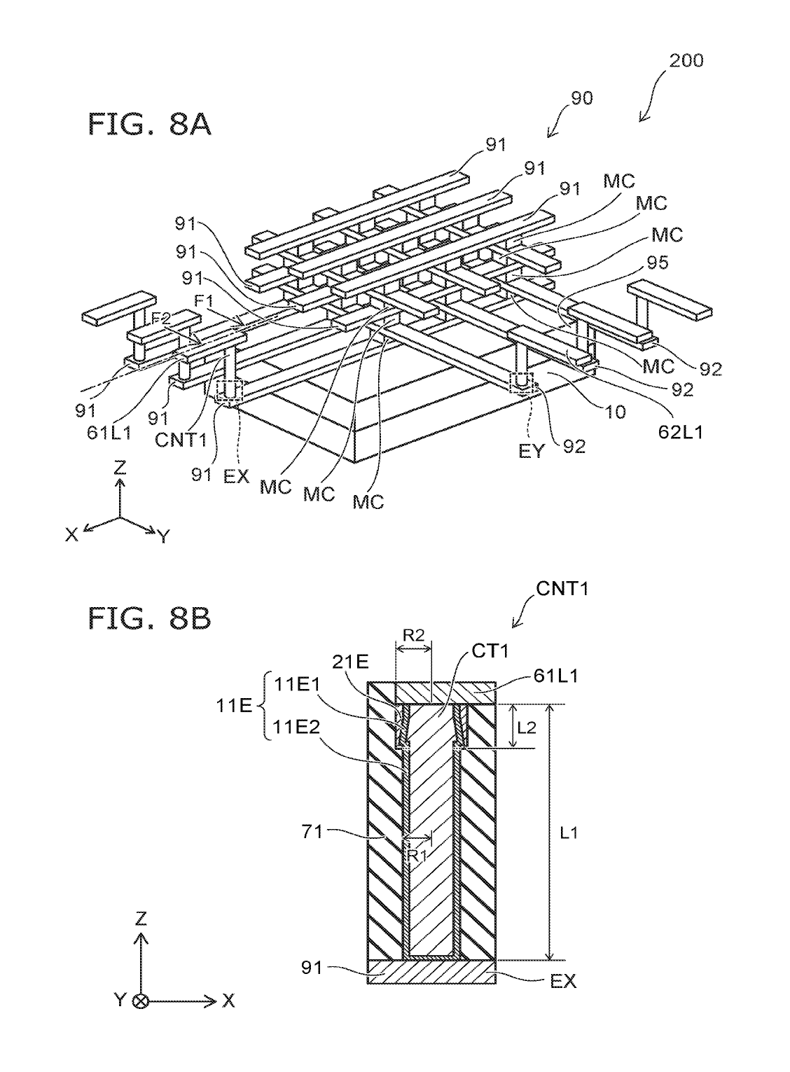

FIG. 8A is a schematic perspective view of a memory device according to a second embodiment.

The semiconductor memory device 200 is, for example, a cross-point type non-volatile resistive memory device.

As shown in FIG. 8A, the substrate 10 is provided in the semiconductor memory device 200. An insulating film 95 is provided on the substrate 10. A stacked body 90 is provided on the insulating film 95. The stacked body 90 includes first interconnects 91 and second interconnects 92. The first interconnect 91 extends in a first extending direction (X). The second interconnect 92 extends in a second extending direction (Y) crossing the first extending direction. The first interconnects 91 and the second interconnects 92 are alternately arranged in a third extending direction (Z) crossing the first extending direction and crossing the second extending direction. The memory cell MC is provided between the first interconnect 91 and the second interconnect 92. The first contact portion CNT1 electrically connected to the first interconnect 91 and extending in the Z-direction is provided. The interconnect 61L1 electrically connected to the first contact portion CNT1 is provided.

FIG. 8B is a schematic sectional view taken along the line F1-F2 shown in FIG. 8A.

As shown in FIG. 8B, the first contact portion CNT1 of the semiconductor memory device 200 according to the second embodiment has a configuration similar to that of the first contact portion CNT1 of the semiconductor memory device 100 according to the first embodiment described above. That is, the first contact portion CNT1 includes the first core material portion CT1, the first conductive film 11E, and the second conductive film 21E.

The first length L1 of the first conductive film 11E along the third extending direction is longer than the second length L2 of the second conductive film 21E along the third extending direction.

The first radius R1 of a circumscribed circle of a cross-section of the second portion 11E2 crossing the third extending direction is, for example, smaller than the second radius R2 of a circumscribed circle of a cross-section of the second conductive film 21E crossing the third extending direction.

The radius of a circumscribed circle of a cross-section of the first portion 11E1 crossing the third extending direction is, for example, smaller than the second radius R2 of the circumscribed circle of the cross-section of the second conductive film 21E crossing the third extending direction.

Moreover, the first contact portion CNT1 of the second embodiment is manufactured in the same manner as the first contact portion CNT1 of the first embodiment. Hence, the first contact portion CNT1 is less likely to have a bowing shape. As a result, also in the second embodiment, it is possible to inhibit contact between the contact portions.

According to the embodiments, it is possible to provide a semiconductor memory device capable of inhibiting contact between contacts and a method for manufacturing the semiconductor memory device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a stacked body including a first electrode film, a second electrode film arranged with the first electrode film in a first direction, and an inter-electrode insulating film provided between the first electrode film and the second electrode film, the first electrode film including a first edge portion not overlapping the second electrode film in the first direction;
a semiconductor pillar provided in the stacked body and extending in the first direction;
a memory film provided between the semiconductor pillar and the first electrode film and provided between the semiconductor pillar and the second electrode film; and
a first contact portion extending in the first direction, overlapping the first edge portion in the first direction and electrically connected to the first edge portion,
the first contact portion including
a first core material portion extending in the first direction,
a first conductive film provided around the first core material portion, the first conductive film including a first portion and a second portion, the second portion being disposed between the first portion and the first edge portion, and
a second conductive film provided around the first portion,
a first length of the first conductive film along the first direction being longer than a second length of the second conductive film along the first direction.

2. The device according to claim 1, wherein
the first core material portion includes a fifth portion and a sixth portion,
the fifth portion is arranged with the second conductive film in the second direction,
the sixth portion is disposed between the fifth portion and the sixth portion, and
a maximum radius of a circumscribed circle of a cross-section of the fifth portion crossing the first direction is larger than a third radius of a circumscribed circle of a cross-section of the sixth portion crossing the first direction.

3. The device according to claim 2, wherein
the fifth portion includes a first face and a second face, the first face facing the sixth portion, the second face being separated from the first face in the first direction,
the maximum radius of the fifth portion is larger than a fourth radius of a circumscribed circle in the first face, and
the maximum radius of the fifth portion is larger than a fifth radius of a circumscribed circle in the second face.

4. The device according to claim 1, wherein
a first radius of a circumscribed circle of a cross-section of the second portion crossing the first direction is smaller than a second radius of a circumscribed circle of a cross-section of the second conductive film crossing the first direction.

5. The device according to claim 1, wherein
the first conductive film includes tungsten.

6. The device according to claim 1, wherein
the second conductive film includes titanium, a first material, or a second material, the first material includes titanium and titanium nitride, the second material includes titanium nitride and tungsten.

7. The device according to claim 1, wherein
the second conductive film includes one of titanium and aluminum.

8. The device according to claim 1, further comprising an interconnect,
the first contact portion is electrically connected with the interconnect.

9. The device according to claim 1, further comprising a second contact portion arranged with the semiconductor pillar in the second direction, arranged with a second edge portion of the second electrode film in the first direction, electrically connected to the second edge portion, and extending in the first direction, wherein
the second contact portion includes
a second core material portion extending in the first direction,
a third conductive film provided around the second core material portion, the third conductive film including a third portion and a fourth portion, the fourth portion being located between the third portion and the second edge portion, and
a fourth conductive film provided around the third portion.

10. A semiconductor memory device comprising:
a first interconnect extending in a first extending direction and including a first edge portion;
a second interconnect extending in a second extending direction crossing the first extending direction, the second interconnect not overlapping the first edge portion in a third extending direction crossing the first extending direction and crossing the second extending direction;
a memory cell provided between the first interconnect and the second interconnect; and
a first contact portion extending in the third extending direction and electrically connected to the first edge portion;
the first contact portion including
a first core material portion extending in the third extending direction,
a first conductive film provided around the first core material portion, the first conductive film including a first portion and a second portion, the second portion being located between the first portion and the first edge portion, and
a second conductive film provided around the first portion,
a first length of the first conductive film along the third extending direction being longer than a second length of the second conductive film along the third extending direction.

11. The device according to claim 10, wherein
a first radius of a circumscribed circle of a cross-section of the second portion crossing the third extending direction is smaller than a second radius of a circumscribed circle of a cross-section of the second conductive film crossing the third extending direction.

12. The device according to claim 10, wherein
the first conductive film includes tungsten.

13. The device according to claim 10, wherein
the second conductive film includes titanium, a first material, or a second material, the first material includes titanium and titanium nitride, the second material includes titanium nitride and tungsten.

14. The device according to claim 10, wherein
the second conductive film includes one of titanium and aluminum.

15. The device according to claim 10, further comprising an interconnect, wherein
the first contact portion is electrically connected with the interconnect.

16. A semiconductor memory device comprising:
a first electrode film including a first edge portion and other portion;
a second electrode film provided on the other portion and separated from the other portion in a first direction, the second electrode film being not disposed on the first edge portion;
a semiconductor pillar extending in the other portion in the first direction;
a memory film provided between the semiconductor pillar and the other portion;
a first contact portion extending in the first direction, disposed on the first edge portion, electrically connected to the first edge portion, and separated from the second electrode film;
a first conductive film provided around the first contact portion and between the first contact portion and the first electrode film; and
a second conductive film provided around a portion of the first conductive film, the portion of the first conductive film being separated from the first electrode film.

17. A method for manufacturing a semiconductor memory device, comprising:
alternately stacking a plurality of inter-electrode insulating films and a plurality of electrode films in a first direction to form a stacked body;
forming a memory hole piercing the stacked body in the first direction;
forming a memory film on a face of the memory hole along the first direction;
forming a semiconductor pillar in the memory hole;
processing the stacked body into a stepped pattern to expose a first edge portion of a first electrode film, the first electrode film being one of the electrode films;
forming a first insulating member on the stacked body processed into the stepped pattern;
removing a portion of the first insulating member to form a first contact hole arranged with the first edge portion in the first direction;
forming a second conductive base film on an inner face of the first contact hole;
forming a second contact hole piercing the second conductive base film and piercing the first insulating member to reach the first electrode film in the first direction;
forming a first conductive film on an inner face of the second contact hole; and
forming a first core material portion filling a remaining space in the second contact hole with a conductive material.
